(19) United States
(12) Patent Application Publication
(10) Pub. No.: US 2008/0001685 A1
(43) Pub. Date: Jan. 3, 2008

(54) Acoustic wave sensor system

(75) Inventor: James ZT Liu, Hudson, NH (US)

Correspondence Address: Kris T. Fredrick;Honeywell International Inc., 101 Columbia Rd., P.O. Box 2245, Morristown, NJ, 07962, US

(73) Assignee: Honeywell International Inc.

(21) Appl. No.: 11/334,989

(22) Filed: Jan. 18, 2006

(51) Int. Cl. H03H 9/00

(52) U.S. Cl. 333/193

(57) ABSTRACT

An interrogation circuit can inductively couple to a sensor and measure the change in fundamental frequency. The change can be used to measure the environmental factor. Sensor sensitivity and inductive coupling efficiency can be competing design constraints. A driver, electrically connected to the sensor and inductively coupled to the interrogation circuit, can relax the constraints. The driver, however, can introduce noise into the sensor. The sensor can be shielded using physical and geometric techniques to reduce the noise.

### TECHNICAL FIELD

Embodiments relate to acoustic wave sensors, sensor systems. Embodiments also relate to using acoustic wave sensors to measure physical properties of liquids.

### BACKGROUND OF THE INVENTION

Acoustic wave sensors are often used to measure the physical properties of liquids such as temperature, density, viscosity, and corrosivity. Those practiced in the art of acoustic wave sensors know of many different types of acoustic wave sensors including surface acoustic wave (SAW) sensors.

FIG. 4, labeled as “prior art”, illustrates one type of acoustic wave device known as a surface acoustic wave device (SAW). FIG. 4 illustrates a graph 401 showing peaks 401, 403 of a respective curves based on a graph 401 of response versus frequency. FIG. 5, labeled as “prior art”, illustrates one type of SAW sensor 501. A first transducer 504 and second transducer 503 are patterned on a piezoelectric substrate 502. An interrogation signal can be passed to the first transducer 504 which converts the interrogation signal into an acoustic wave. The acoustic wave travels through the piezoelectric substrate 502 to the second transducer 503 where it is converted into an output signal. The interrogation signal can be an electrical signal that passes through wired electrical connections. Alternatively, the interrogation signal can be an electromagnetic wave that passes wirelessly through the air. The output signal can also be passed wirelessly or through wires.

Those practiced in the art of acoustic wave devices know of many materials that can be used as piezoelectric substrates. Some of those materials are quartz, lithium niobate (LiNbO₃), lithium tantalite (LiTaO₃), Li₂B₄O₇, GaPO₄, langasite (La₃Ga₅SiO₁₄), ZnO, and epitaxially grown nitrides such as those of Aluminum, Gallium, and Indium.

An acoustic wave sensor has a fundamental frequency at which it responds strongly to an interrogation signal. An interrogation circuit can pass an interrogation signal at a known frequency to the sensor which oscillates in response. The sensor oscillations can then be observed by the interrogation circuit. Changes to the sensor's environment can cause changes to the sensor's fundamental frequency.

Measurements of changes fundamental frequency changes can therefore yield measurements of the sensor's environment. For example, increasing a sensor's temperature can cause the fundamental frequency to increase. Exposing the sensor to a corrosive liquid can also cause the fundamental frequency to increase. Similarly, exposing the sensor to a liquid and then increasing the liquid's density can cause the fundamental frequency to increase. It can be difficult, however, to produce a meaningful measurement when more than one environmental factor is changing.

FIG. 6, labeled as “prior art”, illustrates a graph 601 of sensor Q, also called the quality factor, changing in response to changing viscosity. When exposed to a liquid having a low viscosity, the sensor responds strongly as indicated by the first response curve 602. Raising the liquid viscosity, however, reduces the sensor response as indicated by the second response curve 603. The response curves indicate how strongly the sensor responds to interrogation signals having different frequencies. The first curve 602 shows that the sensor has a higher Q when the liquid has lower viscosity. Those skilled in the arts of sensors or amplifiers are familiar with Q. Those skilled in the art of measuring the properties of liquids are familiar with the effect of a liquid's viscosity on acoustic wave sensor Q.

Sensor measurement accuracy can be significantly degraded when many environmental factors change. For example, an acoustic sensor measuring a liquid's temperature can produce spurious results when density or viscosity change while temperature remains constant. Current technology requires the use of multiple sensors producing many different measurements. Mathematical analysis of the different measurements can isolate one environmental factor from the others so that an accurate measurement can be made.

Another approach that has been used to produce less degraded measurements is to use a coating to protect the acoustic wave sensor from corrosion. As discussed above, corrosion can cause the fundamental frequency to increase. A problem occurs when a temperature sensor shows a slowly increasing temperature that is, in reality, sensor corrosion. Coating the sensor with a material that resists corrosion solves the problem. Hydrophobic coating materials repel water while hydrophilic coating materials do not. Tantalum, Silicon Carbide, and Silicon Dioxide can be used as coating materials. Carbon can be used as a coating material in either diamond, buckyball, or nanotube form. Fluorinated polymers such as Teflon can also be used as coating materials.

Aspects of the embodiments directly address the shortcoming of current technology by characterizing the acoustic sensor, liquid, coating material, and coating thickness to avoid measurement degradations due to viscosity variations.

### BRIEF SUMMARY

The following summary is provided to facilitate an understanding of some of the innovative features unique to the embodiments and is not intended to be a full description. A full appreciation of the various aspects of the embodiments can be gained by taking the entire specification, claims, drawings, and abstract as a whole.

It is therefore an aspect of the embodiments to provide a sensor that contains and acoustic wave device electrically connected to a spiral inductor and to use an interrogation circuit to interrogate the sensor. The interrogation circuit, containing a grid dip oscillator (GDO), inductively couples with the spiral inductor and measures the fundamental frequency. Surface acoustic wave (SAW) devices and bulk acoustic wave (BAW) devices are examples of acoustic wave devices. Shielding techniques are used to inhibit the acoustic wave device from becoming inductively coupled with other elements such as the spiral inductor or the interrogation circuit.

It is an aspect of certain embodiments to use a shielding technique wherein a guard ring can be placed around either the acoustic wave device or the spiral inductor. A guard ring is a conductive trace surrounding, or nearly surrounding, a circuit element. The guard ring is usually connected to circuit ground and thereby helps prevent noise from reaching the enclosed circuit element or from escaping from the enclosed circuit element. Guard rings are most effective in protecting coplanar elements, meaning they geometrically lie substantially on the same plane, from one another. In many cases, circuit elements are exposed to noise sources that are not coplanar, in which case a shield of conductive material is used. The shield substantially encloses the circuit elements. A guard ring can be thought of as a two dimensional shield that works in special circumstances.

It is an aspect of some embodiments to use geometric shielding. Historically, the simplest type of shielding, called “one over r squared shielding” is to place a sensitive component far from noise sources. Distance, however, is rarely available in a compact system and rarely appropriate for real world situations. A small amount of distance can have a large effect in some circumstances. As dictated by the laws of physics, the fundamental frequency, discussed above, is inversely related to a fundamental wavelength. Separating the acoustic wave device and the spiral inductor by a few fundamental wavelengths can have a large effect on inductive coupling.

Inductive coupling occurs most efficiently when the electromagnetic fields of two or more inductive circuit elements line up. Misaligning the fields can significantly reduce inductive coupling. Rotation and lateral shifts can cause significant misalignment and thereby reduce the inductive coupling.

### BRIEF DESCRIPTION OF THE DRAWINGS

The accompanying figures, in which like reference numerals refer to identical or functionally similar elements throughout the separate views and which are incorporated in and form a part of the specification, further illustrate the present invention and, together with the background of the invention, brief summary of the invention, and detailed description of the invention, serve to explain the principles of the present invention.

FIG. 1 illustrates a sensor module inductively coupled to an interrogation circuit in accordance with an embodiment;

FIG. 2 illustrates a sensor module with a guard ring around an acoustic wave device in accordance with an embodiment;

FIG. 3 illustrates an acoustic wave device laterally displaced and rotated in relation to a spiral inductor in accordance with an embodiment;

FIG. 4, labeled as “prior art”, illustrates one type of acoustic wave device known as a surface acoustic wave device (SAW);

FIG. 5, labeled as “prior art”, illustrates another type of acoustic wave device called a bulk acoustic wave device (BAW);

FIG. 6, labeled as prior art, illustrates an inductively coupled interrogation circuit 601; and

FIG. 7 illustrates a high level flow diagram of using a shielded sensor.

### DETAILED DESCRIPTION

The particular values and configurations discussed in these non-limiting examples can be varied and are cited merely to illustrate at least one embodiment and are not intended to limit the scope thereof. In general, the figures are not to scale.

FIG. 1 illustrates a sensor module 102 inductively coupled to an interrogation circuit 101 in accordance with an embodiment. As discussed above, the interrogation circuit 101 can contain a grid dip oscillator (GDO) 108. The interrogation circuit 101 is inductively coupled to a spiral inductor 103 with the inductive coupling indicated by a two headed arrow 106. The spiral inductor 103 is surrounded by a guard ring 105 to minimize the coupling between the spiral inductor 103 and an acoustic wave device 105 to which it is electrically connected. In the system of FIG. 1, the acoustic wave device is open to noise sources other than the spiral inductor 103. Furthermore, the interrogation circuit 101 must be physically arranged to defeat the shielding properties of the guard ring 105 such as placing them on different planes and ensuring that the fields otherwise align.

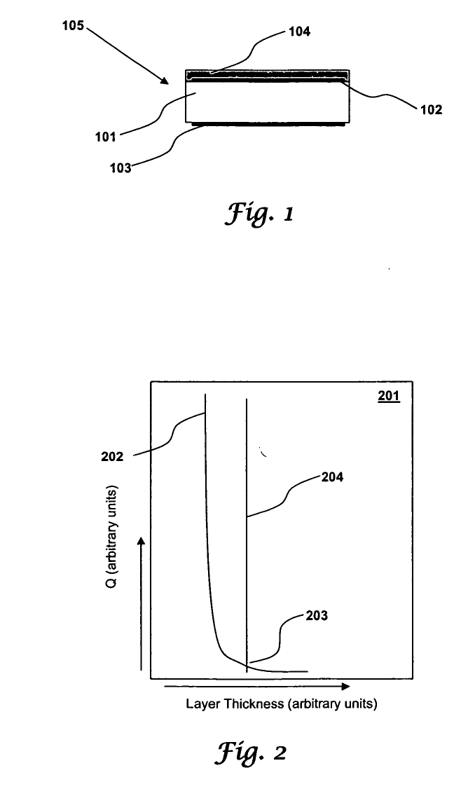

FIG. 2 illustrates a sensor module 201 with a guard ring 105 around an acoustic wave device 104 in accordance with an embodiment. In the system of FIG. 2, the acoustic wave device 104 is shielded from many sources of inductive coupling.

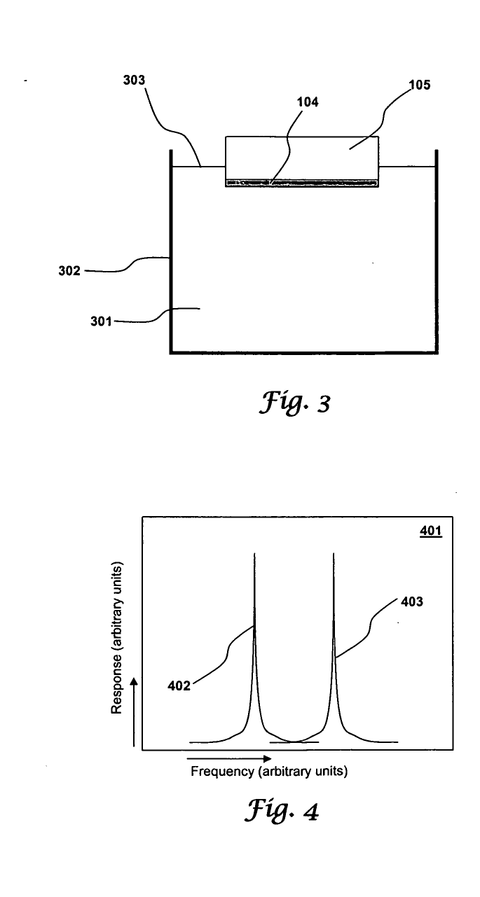

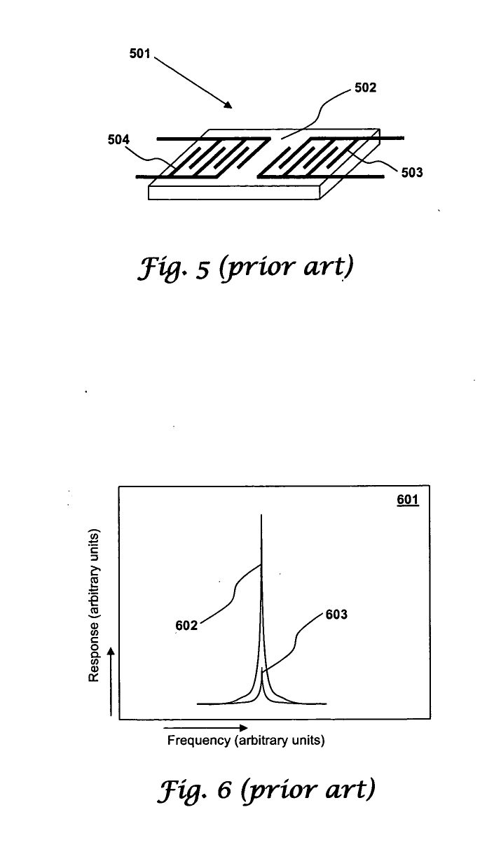

FIG. 3 illustrates an acoustic wave device 104 laterally displaced and rotated in relation to a spiral inductor 103 in accordance with an embodiment. The plane of the acoustic wave device 104 is rotated approximately 90 degrees from that of the spiral inductor 103. The circling arrow 303 indicates that the planes are rotated in relation to one another. The straight arrow 302 indicates lateral displacement. The spiral inductor 103 and the acoustic wave device 104 are shown sharing a central axis 301. More generally, the devices do not need to share a central axis 301. Lateral displacement means “moved” but does not mean “moved along an axis”. Furthermore, the illustration shows 90 degrees of rotation, which is optimal. In practice, angles between 85 and 95 degrees will work well while angles between 60 and 120 degrees can provide acceptable results.

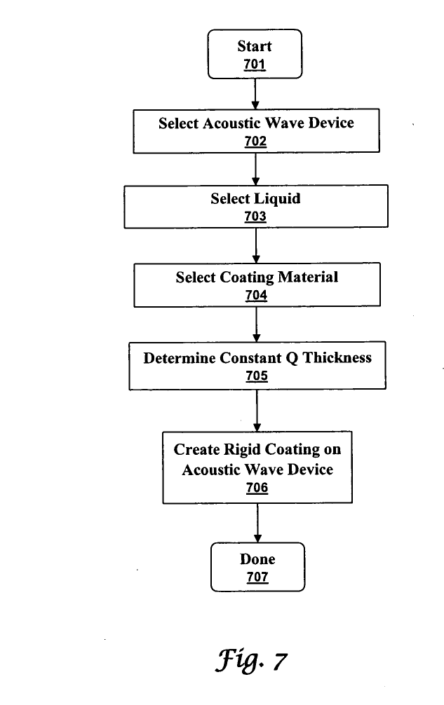

FIG. 7 illustrates a high level flow diagram of using a shielded sensor. After the start 701 a sensor containing a spiral inductor and an acoustic wave device is provided 702. The acoustic wave device is then shielded 703. For example, the acoustic wave device can be rotated and displaced laterally with respect to the spiral inductor. The sensor's fundamental frequency is then measured 704. An interrogation circuit containing a GDO can be used for the fundamental frequency measurement. Finally, the process is done 705.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A system comprising:
a sensor comprising an acoustic wave device electrically connected to a spiral inductor wherein the sensor has a fundamental frequency that changes in response to environmental factors such as temperature, pressure, or chemicals;
an interrogation circuit that measures the fundamental frequency wherein the interrogation circuit is inductively coupled to the spiral inductor, and wherein the interrogation circuit comprises a grid dip oscillator; and
a shield inhibiting inductive coupling to the acoustic wave device.

2. The system of claim 1 wherein the spiral inductor and the acoustic wave device are coplanar and wherein the shield is a guard ring surrounding the spiral inductor.

3. The system of claim 2 wherein the acoustic wave device is a surface acoustic wave device;

4. The system of claim 2 wherein the acoustic wave device is a bulk acoustic wave device;

5. The system of claim 1 wherein the spiral inductor and the acoustic wave device are coplanar and wherein the shield is a guard ring surrounding the acoustic wave device.

6. The system of claim 5 wherein the acoustic wave device is a surface acoustic wave device;

7. The system of claim 5 wherein the acoustic wave device is a bulk acoustic wave device;

8. The system of claim 1 wherein the shield comprises a conductive material enclosing the acoustic wave device.

9. A system comprising:
a sensor comprising an RLC sensor and electrically connected to a spiral inductor, wherein the sensor has a fundamental frequency that changes in response to environmental factors such as temperature, pressure, or chemicals;
an interrogation circuit that measures the fundamental frequency wherein the interrogation circuit is inductively coupled to the spiral inductor, and wherein the interrogation circuit comprises a grid dip oscillator; and
wherein the placement of the RLC sensor in relation to the spiral inductor and the interrogation circuit produces a geometric shield inhibiting inductive coupling to the acoustic wave device.

10. The system of claim 9 wherein the RLC sensor is rotated and displaced laterally in relation to the spiral inductor and the interrogation circuit.

11. The system of claim 10 wherein the RLC sensor comprises a PTC or NTC type resistor;

12. The system of claim 10 wherein the RLC sensor is a resistive pressure sensor;

13. The system of claim 10 wherein the RLC sensor is a capacitive pressure sensor;

14. The system of claim 10 wherein the RLC sensor is an inductive pressure sensor;

15. The system of claim 9 wherein a fundamental period is a distance inversely related to the fundamental frequency and wherein the geometric shield comprises placing the acoustic wave device more than 4 fundamental periods from the spiral inductor and from the interrogation circuit.

16. A method comprising:
providing a sensor comprising a passive sensor electrically connected to a spiral inductor wherein the sensor has a fundamental frequency that changes in response to environmental factors such as temperature, pressure, or chemicals;
shielding the passive sensor from inductive coupling; and
measuring the fundamental frequency with an interrogation circuit inductively coupled to the spiral inductor wherein the interrogation circuit comprises a grid dip oscillator.

17. The system of claim 16 wherein shielding comprises:
rotating the passive sensor in relation to the spiral inductor and the interrogation circuit; and
laterally displacing the passive sensor from the spiral inductor and the interrogation circuit.

18. The system of claim 17 wherein the passive sensor comprises a surface acoustic wave device.

19. The system of claim 17 wherein the passive sensor is a RLC sensor.

20. The system of claim 17 wherein the passive sensor comprises a magneto-elastic or magneto-strictive type device.
